(19) United States
(12) Patent Application Publication
(10) Pub. No.: US 2013/0228219 A1
(43) Pub. Date: Sep. 5, 2013

(54) SOLAR CELL, AND METHOD OF MANUFACTURING THE SAME

(71) Applicant: PANASONIC CORPORATION, Osaka (JP)

(72) Inventors: Yoshinori SHISHIDA, Osaka (JP); Mitsuo SAITOH, Osaka (JP)

(73) Assignee: PANASONIC CORPORATION, Osaka (JP)

(21) Appl. No.: 13/767,620

(22) Filed: Feb. 14, 2013

(30) Foreign Application Priority Data
Mar. 2, 2012 (JP) 2012-046006

(51) Int. Cl. H01L 31/0224; H01L 31/18

(52) U.S. Cl. CPC H01L 31/022425; H01L 31/1884
USPC 136/256; 438/98

(57) ABSTRACT

A first electrode layer (202) that is a multilayer electrode, a photoelectric conversion layer (206), and an ITO layer (210) are sequentially disposed on a glass substrate (201). The ITO layer (210) is a transparent electrode layer serving as a second electrode layer. The first electrode layer (202) includes a Cr layer (203), a mixed layer (204) of Cr and ZnO, and a ZnO layer (205) that are stacked in this order when viewed from the glass substrate (201). The content of Cr in the mixed layer (204) gradually increases toward the Cr layer (203), thereby preventing exfoliation on the Cr layer (203) and the ZnO layer (205) for a long time.

### Field of the Invention

The present invention relates to a solar cell and a method of manufacturing the same, and particularly relates to the structure of a multilayer electrode of the solar cell.

### BACKGROUND OF THE INVENTION

Products requiring a large amount of electric power, e.g., all-electric houses and electric vehicles have been currently introduced to the market, and thus the demand for electricity has increased year by year. It has been, however, difficult to increase the number of thermal power plants and nuclear power plants in fear of carbon dioxide emission and radioactive contamination. For this reason, the widespread use of clean energy has been demanded. Particularly, photovoltaic power generation has received attention because of its infinite and pollution-free energy resource (sunlight).

Solar cells using Si crystals have been the most popular in photovoltaic power generation but are still expensive for 1W. Thus, inexpensive thin-film solar cells have been actively studied. Roll-to-roll processes using stainless steel or resin substrates have been examined to achieve lower cost. Japanese Patent No. 3093504 describes an example of a thin-film solar cell including a silicon layer having an amorphous phase. Referring to FIG. 6, the contents will be described below.

A multilayer lower electrode 102 including an Ag layer 103 and a ZnO transparent conductive layer 104 is stacked on a stainless steel (Steel Use Stainless) substrate 101 having an insulated surface (hereinafter, will be called a SUS substrate 101). Moreover, a power generation layer 105 including an n-type (or p-type) Si semiconductor layer 106, an i-type semiconductor layer 107, and a p-type (n-type) Si semiconductor layer 108 is formed thereon. Furthermore, an ITO layer 109 is formed on the p-type (n-type) Si semiconductor layer 108 to efficiently collect electric power, and then Ag electrodes 110 are formed thereon.

As illustrated in this example, typically, the multilayer lower electrode 102 disposed below a light entry face has a laminated structure including the ZnO transparent conductive layer 104 made of a transparent conductive material and the Ag layer 103 made of a metallic material. This configuration is expected to achieve satisfactory electrical conduction between a power generation layer and an electrode, suppress the influence of metallic impurities caused by the diffusion of a metallic material, e.g., the Ag electrode 103 into the power generation layer 105, and improve a light confinement effect obtained by reflection on the interface between a power generation material and a transparent conductive material, the interface being caused by a refractive index difference between the power generation material and the transparent conductive material.

In the conventional thin-film solar cell using the multilayer electrode, however, the interface between the metallic material and the transparent conductive material may have exfoliation in long-term use at a high temperature and humidity, disadvantageously deteriorating solar cell characteristics.

To address this problem, a structure illustrated in FIG. 7 of Japanese Patent Laid-Open No. 2002-151720 avoids exfoliation caused by long-term use. Specifically, in a multilayer lower electrode 111, an Ag alloy layer 112 containing Ag and other metals is provided between an Ag layer 113 and a transparent conductive layer 114, thereby improving adhesion between the Ag layer 113 and the transparent conductive layer 114.

Japanese Patent Laid-Open No. 6-204533 describes a thin-film solar cell in which a mixed layer of an insulator and a metal is disposed between a substrate and a semiconductor layer.

Japanese Patent Laid-Open No. 9-87860 describes a thin-film solar cell that includes a silver thin film formed between an underlying layer containing silicon and an intermediate thin film containing silver, oxygen, and metallic elements constituting a metallic oxide having transparent conductivity.

Japanese Patent Laid-Open No. 2004-55745 describes a thin-film solar cell including an intermediate layer, a metallic layer, and a metallic oxide layer that are joined between a substrate and a semiconductor layer.

Japanese Patent Laid-Open No. 2011-82295 describes a thin-film solar cell including multiple layers stacked and joined with different coefficients of thermal expansion between a substrate and a semiconductor layer.

US2010/0071810 describes a thin film deposited on a substrate. The surface of the thin film is heated to 300° C. or higher in a short time, so that a temperature on a surface of the substrate opposite to the deposited thin film is suppressed to 150° C. or lower.

US2012/0060916 describes a thin-film solar cell including an Ag layer, an overcoat layer, and a transparent conductive film that are joined between a substrate and a semiconductor layer.

### Disclosure of the Invention

In the method of Japanese Patent Laid-Open No. 2002-151720, however, the alloy layer is introduced into the conventional structure and thus the introduction of a new material may interfere with cost reduction that is an original object. Also in the techniques of Japanese Patent Laid-Open No. 6-204533, Japanese Patent Laid-Open No. 9-87860, Japanese Patent Laid-Open No. 2004-55745, Japanese Patent Laid-Open No. 2011-82295, US2010/0071810, and US2012/0060916, it is difficult to avoid exfoliation caused by long-term use.

The present invention has been devised to solve the problem. An object of the present invention is to provide a thin-film solar cell and a method of manufacturing the same, which prevent exfoliation caused by long-term use while avoiding cost increase in the thin-film solar cell including a multilayer electrode.

### BRIEF DESCRIPTION OF THE DRAWINGS

FIG. 1 is a schematic diagram illustrating the laminated structure of a solar cell according to a first embodiment of the present invention;

FIGS. 2(a) to 2(d) are process drawings showing a manufacturing flow of the solar cell according to the first embodiment of the present invention;

FIGS. 3(a) to 3(e) are process drawings showing a manufacturing flow of a solar cell according to a second embodiment of the present invention;

FIG. 4 is a schematic drawing illustrating the configuration of a solar cell according to a third embodiment of the present invention;

FIGS. 5(a) to 5(e) are process drawings showing a manufacturing flow of the solar cell according to the third embodiment of the present invention;

FIG. 6 is a schematic diagram illustrating the laminated structure of a solar cell in Japanese Patent No. 3093504 and so on; and

FIG. 7 is a schematic diagram illustrating the laminated structure of a solar cell in Japanese Patent Laid-Open No. 2002-151720 and so on.

### DESCRIPTION OF THE EMBODIMENTS

Embodiments of the present invention will be described below with reference to the accompanying drawings.

### First Embodiment

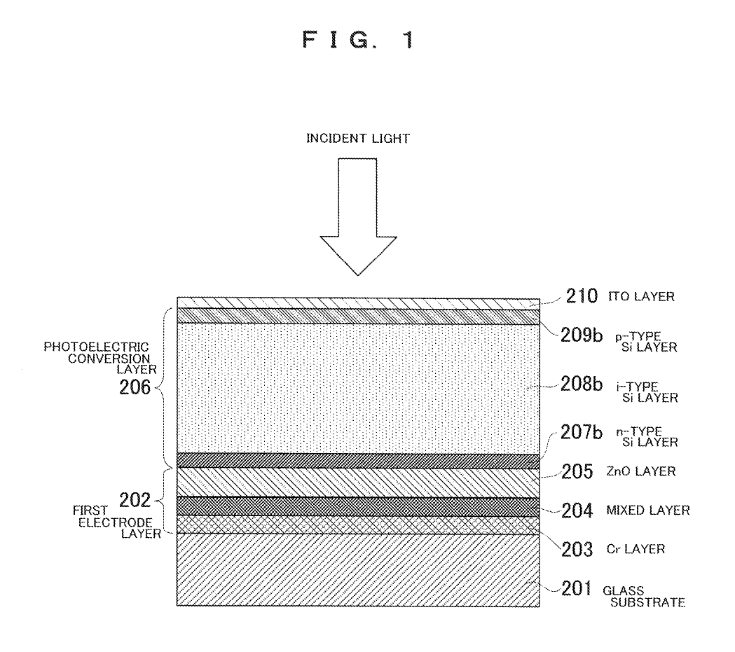

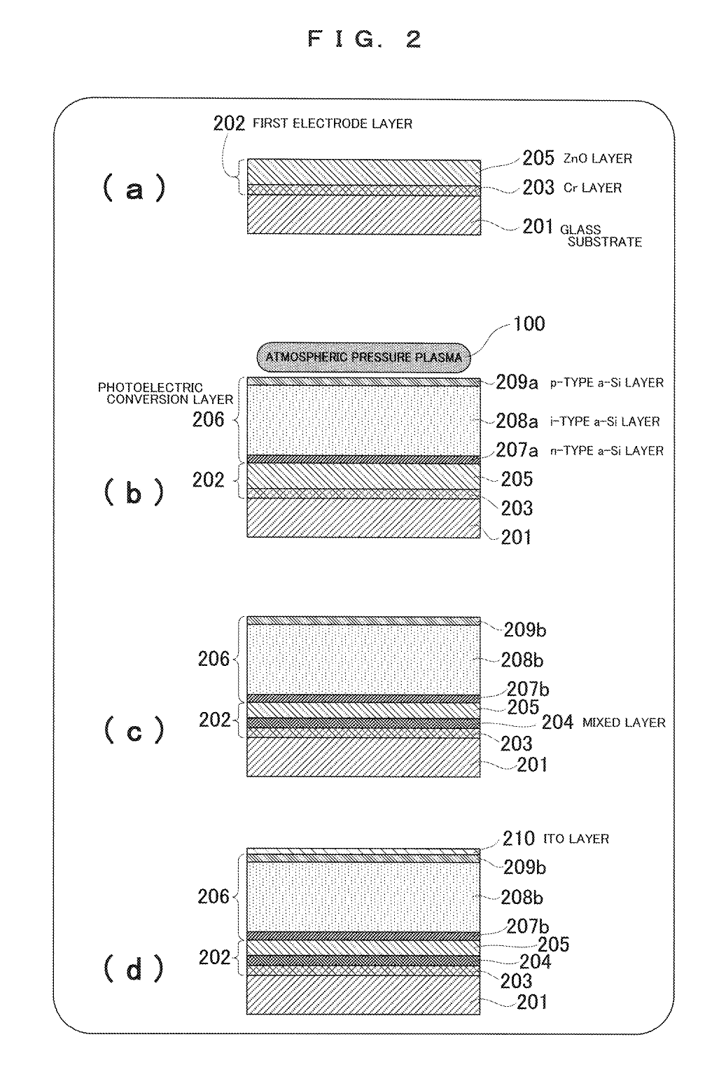

FIGS. 1 and 2(a) to 2(d) illustrate a first embodiment of the present invention.

As illustrated in FIG. 1, a solar cell having a substrate structure according to the present invention has a laminated structure in which a first electrode layer 202 serving as a multilayer electrode, a photoelectric conversion layer 206, and an ITO layer 210 that is a transparent electrode layer serving as a second electrode layer are sequentially stacked on a glass substrate 201 having electrical insulation.

The first electrode layer 202 serving as an underlying electrode includes a Cr layer 203, a mixed layer 204 of Cr and ZnO, and a ZnO layer 205 that are stacked in this order from the glass substrate 201.

The photoelectric conversion layer 206 has a laminated structure including an n-type Si layer 207b, an i-type Si layer 208b, and a p-type Si layer 209b that are stacked in this order when viewed from the first electrode layer 202.

The solar cell can be fabricated in the steps of FIGS. 2(a) to 2(d).

As illustrated in FIG. 2(a), the Cr layer 203 having a thickness of about 500 nm is first deposited as a metallic material layer by sputtering on the heat-resistant glass substrate 201 having a thickness of about 400 μm to 1000 μm, and then the ZnO layer 205 having a thickness of about 100 nm is deposited thereon as a transparent conductive film material layer.

As illustrated in FIG. 2(b), the photoelectric conversion layer 206 having an amorphous phase is then deposited on the ZnO layer 205 by sputtering. The photoelectric conversion layer 206 includes an n-type a-Si layer 207a, an i-type a-Si layer 208a, and a p-type a-Si layer 209a that are deposited in this order when viewed from the ZnO layer 205. The n-type a-Si layer 207a is deposited by the sputtering using a sputtering target doped with P. The i-type a-Si layer 208a is deposited by a sputtering target having a low impurity density. The p-type a-Si layer 209a is deposited by a sputtering target doped with B.

The processed article in FIG. 2(b) receives a quantity of heat from the surface of the p-type a-Si layer 209a by atmospheric pressure plasma 100 according to an atmospheric plasma technique. The quantity of heat is supplied to change the crystal of an amorphous phase, activate impurities such as B and P, and form the mixed layer 204 by thermal diffusion on a lower electrode. The quantity of heat is supplied to cause a-Si to change the layers, so that the photoelectric conversion layer 206 in FIG. 2(c) includes the n-type Si layer 207b, the i-type Si layer 208b, and the p-type Si layer 209b that are stacked in this order when viewed from the ZnO film 205.

The quantity of heat is supplied by the atmospheric pressure plasma technique to heat-treat the interface between the ZnO layer 205 and the Cr layer 203 to at least 300° C.

Finally, the layers are subjected to wet cleaning, and then as illustrated in FIG. 2(d), the ITO layer 210, a transparent conductive layer serving as a second electrode layer, is deposited to a thickness of about 100 nm by sputtering. In the wet cleaning, the layers are immersed into HF of 1% for about ten minutes to remove an oxide film (not shown) formed on the surface of a sample.

In the solar cell fabricated in this process, the mixed layer 204 tightly joins the Cr layer 203 that is a metallic material layer and a ZnO layer 205 that is a transparent conductive film material layer, thereby avoiding exfoliation in long-term use.

In the present embodiment, the flat and heat-resistant glass substrate 201 is a substrate material. The glass substrate 201 may be a glass substrate provided with a texture surface, a SUS substrate having an insulated surface, or a blue sheet glass that is less heat resistant and less expensive.

In the present embodiment, the metallic material is Cr. Cr may be replaced with one of W, Ag, Cu, Al, Mo, Au, Al, and Ti or an alloy containing W, Ag, Cu, Al, Mo, Au, Al, and Ti.

In the present embodiment, the photoelectric conversion layer 206 includes the n-type layer, the i-type layer, and the p-type layer that are deposited in this order when viewed from the ZnO layer 205. The configuration is not particularly limited. The order of deposition may be the p-type layer, the i-type layer, and the n-type layer, or the n-type layer and the p-type layer and vice versa without the i-type layer.

In the present embodiment, the transparent conductive film material layer contains ZnO while the second electrode layer contains ITO. The transparent conductive film material layer and the second electrode layer are not particularly limited and thus may contain ZnO, ITO, and SnO₂ or a transparent conductive metal oxide material mainly composed of ZnO, ITO, and SnO₂.

In the present embodiment, the mixed layer 204 is formed by the atmospheric pressure plasma technique. A method for metal diffusion is not limited to the atmospheric pressure plasma technique. Short-time processing can be achieved by at least one of atmospheric plasma, flash lamp annealing, and laser ablation, thereby advantageously reducing a stress caused by heat to the glass substrate 201.

In the present embodiment, the mixed layer 204 formed by metal diffusion contains no metallic materials on the interface of the transparent conductive film material layer. The content of a metallic material gradually increases toward the metallic material layer, and only the metallic material remains on the interface of the metallic material layer. In this structure, the interfaces of the metallic material layer, the mixed layer, and the transparent conductive film material layer are eliminated, further suppressing exfoliation caused by interfaces during long-term use.

### Second Embodiment

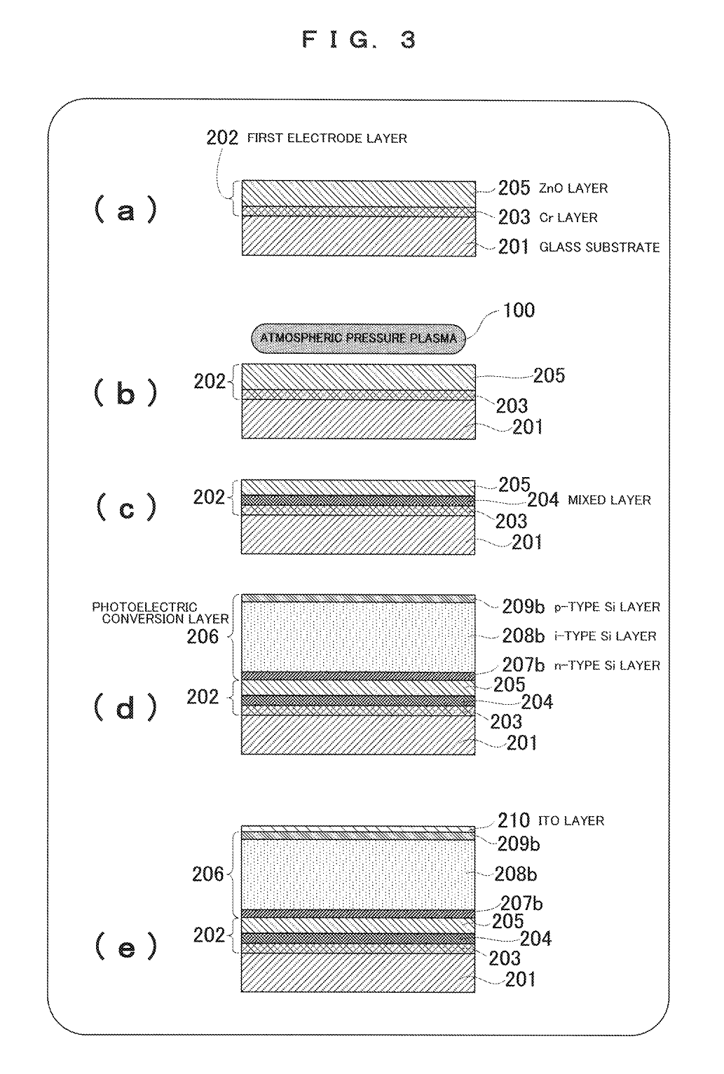

FIGS. 3(a) to 3(e) illustrate a second embodiment of the present invention.

A manufacturing method according to the second embodiment additionally includes the step of forming a mixed layer by using an atmospheric pressure plasma technique after the deposition of a ZnO layer 205 having a thickness of about 100 nm.

Other steps and materials are similar to those of the first embodiment. The second embodiment can more sufficiently apply heat near the interface between a metallic material layer and a transparent conductive film material layer, allowing sufficient thermal diffusion of metals so as to reliably form the mixed layer.

In FIG. 3(a), a Cr layer 203 having a thickness of about 500 nm is first deposited by sputtering as a metallic material layer on a heat-resistant glass substrate 201 having a thickness of about 400 μm to 1000 μm, and then a ZnO layer 205 having a thickness of about 100 nm is deposited thereon as a transparent conductive film material layer.

In FIG. 3(b), a quantity of heat is supplied from the surface of the ZnO layer 205 by atmospheric pressure plasma 100 according to an atmospheric pressure plasma technique. The quantity of heat is supplied by the atmospheric pressure plasma technique to heat-treat the interface between the ZnO layer 205 and the Cr layer 203 to at least 300° C. Thus, as illustrated in FIG. 3(c), the metal of the Cr layer 203 is diffused to the ZnO layer 205 so as to form a mixed layer 204 on the interface between the ZnO layer 205 and the Cr layer 203.

In FIG. 3(d), a processed article illustrated in FIG. 3(c) further includes a photoelectric conversion layer 206 formed on the ZnO layer 205.

Finally, the layers are subjected to wet cleaning, and then as illustrated in FIG. 3(e), an ITO layer 210, a transparent conductive layer serving as a second electrode layer, is deposited to a thickness of about 100 nm by sputtering. In the wet cleaning, the layers are immersed into HF of 1% for about ten minutes to remove an oxide film (not shown) formed on the surface of a sample.

### Third Embodiment

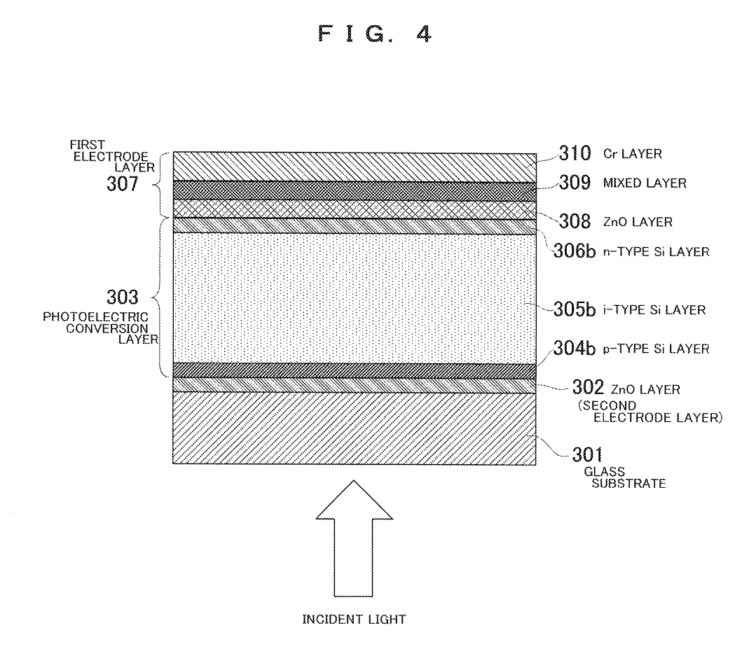

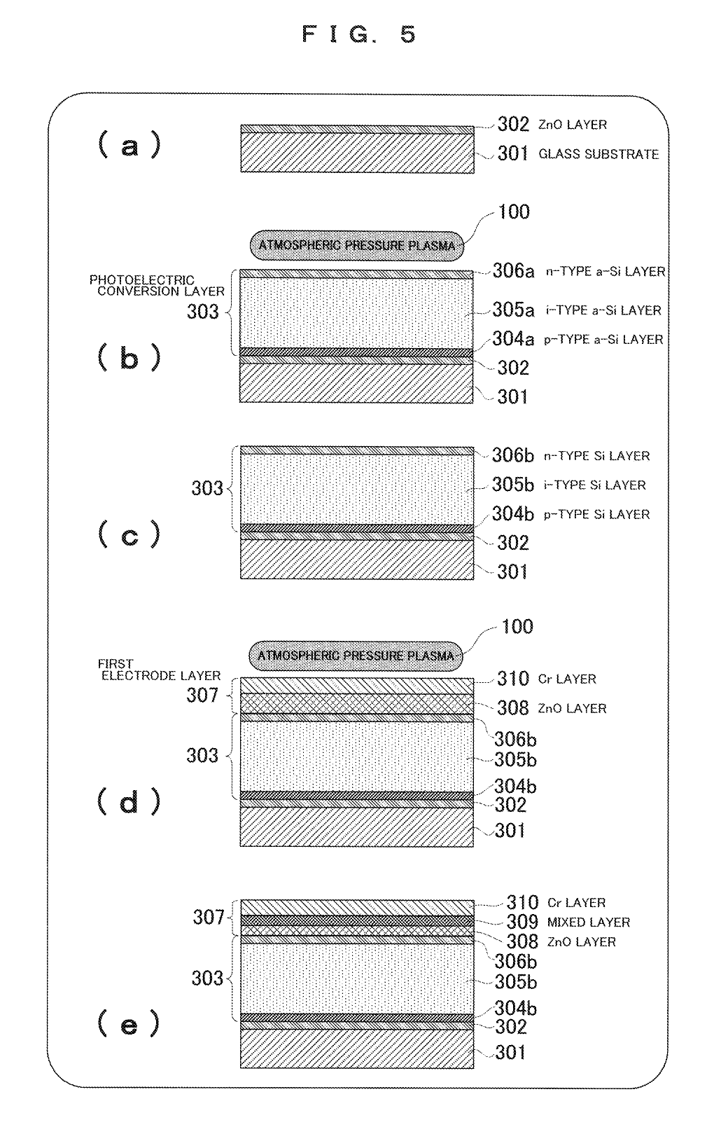

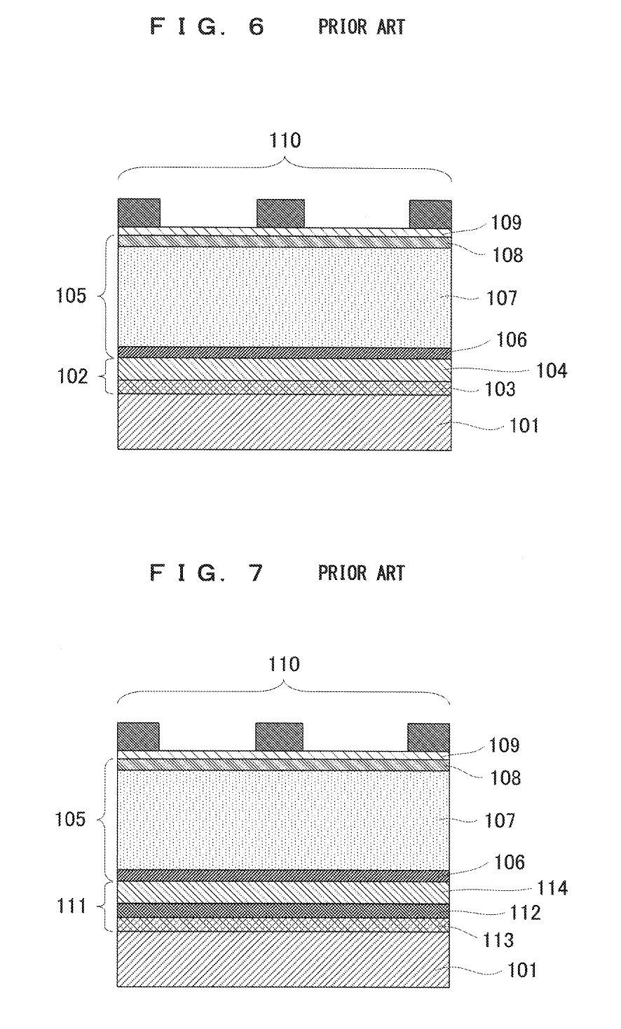

FIGS. 4 and 5 illustrate a third embodiment of the present invention.

As illustrated in FIG. 4, a solar cell having a substrate structure according to the third embodiment includes a ZnO layer 302, a photoelectric conversion layer 303, and a first electrode layer 307 that are sequentially stacked on a glass substrate 301. The ZnO layer 302 is a second electrode layer serving as a transparent electrode layer, and the first electrode layer 307 serves as a multilayer electrode.

The first electrode layer 307 includes a Cr layer 310, a mixed layer 309 of Cr and ZnO, and a ZnO layer 308 that are stacked in this order when viewed from the glass substrate 301. The photoelectric conversion layer 303 has a laminated structure including an n-type Si layer 306b, an i-type Si layer 305b, and a p-type Si layer 304b that are stacked in this order from the first electrode layer 307.

The solar cell can be fabricated in the steps of FIGS. 5(a) to 5(e).

First, in FIG. 5(a), the ZnO layer 302 having a thickness of about 100 nm is deposited by sputtering on the heat-resistant glass substrate 301 having a thickness of about 400 μm to 1000 μm. The ZnO layer 302 is a transparent conductive layer serving as a second electrode layer.

Then, in FIG. 5(b), the photoelectric conversion layer 303 having an amorphous phase is deposited by sputtering on the ZnO layer 302 serving as the second electrode layer.

The photoelectric conversion layer 303 includes a p-type a-Si layer 304a, an i-type a-Si layer 305a, and an n-type a-Si layer 306a that are deposited in this order when viewed from the ZnO layer 302 serving as the second electrode layer.

The layers are deposited by sputtering. The p-type a-Si layer 304a is deposited by a sputtering target doped with B, the i-type a-Si layer 305a is deposited by a sputtering target having a low impurity density, and the n-type a-Si layer 306a is deposited by a sputtering target doped with P.

A quantity of heat is supplied from the surface of the n-type a-Si layer 306a by atmospheric pressure plasma 100 according to an atmospheric pressure plasma technique. The quantity of heat is supplied to change the crystal of an amorphous phase and activate impurities such as B and P.

Thus, as illustrated in FIG. 5(c), the quantity of heat supplied in FIG. 5(b) causes a-Si to change the layers, so that the photoelectric conversion layer 303 includes an n-type Si layer 304b, an i-type Si layer 305b, and a p-type Si layer 306b that are stacked in this order when viewed from the ZnO layer 302 serving as the second electrode layer.

In FIG. 5(d), the layers are subjected to wet cleaning, and then the ZnO layer 308 serving as a transparent conductive film material layer is deposited to a thickness of about 100 nm. The Cr layer 310 serving as a metallic material layer is then deposited to a thickness of about 500 nm.

Furthermore, a quantity of heat is supplied from the surface of the Cr layer 310 by the atmospheric pressure plasma 100 according to the atmospheric pressure plasma technique. The quantity of heat is supplied to heat-treat the interface between the ZnO layer 308 and the Cr layer 310 to at least 300° C. Thus, as illustrated in FIG. 4(e), the mixed layer 309 is formed on the interface between the Cr layer 310 and the ZnO layer 308 by thermal diffusion of Cr.

Finally, the layers are immersed into HF of 1% for about ten minutes to undergo wet cleaning. The wet cleaning is aimed at removing an oxide film (not shown) formed on the surface of a sample.

In the solar cell fabricated by this process, the mixed layer 309 tightly joins the metallic material layer and the transparent conductive film material layer, thereby avoiding exfoliation in long-term use.

In the present embodiment, the metallic material is Cr. Cr may be replaced with one of W, Ag, Cu, Al, Mo, Au, and Ti or an alloy containing W, Ag, Cu, Al, Mo, Au, and Ti.

In the present embodiment, the photoelectric conversion layer 303 includes the n-type layer, the i-type layer, and the p-type layer that are deposited in this order when viewed from the ZnO layer 302 serving as the second electrode layer. The configuration is not particularly limited. The order of deposition may be the p-type layer, the i-type layer, and the n-type layer, or the n-type layer and the p-type layer and vice versa without the i-type layer.

In the present embodiment, the transparent conductive film material layer and the second electrode layer contain ZnO. The transparent conductive film material layer and the second electrode layer are not particularly limited and thus may contain ZnO, ITO, and SnO₂ or a transparent conductive metal oxide material mainly composed of ZnO, ITO, and SnO₂.

In the present embodiment, the mixed layer is formed by the atmospheric pressure plasma technique. A method for metal diffusion is not limited to the atmospheric pressure plasma technique. Short-time processing can be achieved by at least one of atmospheric pressure plasma, flash lamp annealing, and laser ablation, thereby advantageously reducing a stress caused by heat to the glass substrate 301.

In the present embodiment, the mixed layer formed by metal diffusion contains no metallic materials on the interface of the transparent conductive film material layer. The content of the metallic material gradually increases toward the metallic material layer, and only the metallic material remains on the interface of the metallic material layer. In this structure, the interfaces of the metallic material layer, the mixed layer, and the transparent conductive film material layer are eliminated, further suppressing exfoliation caused by interfaces during long-term use.

In the structures of the mixed layers 204 and 309 according to the foregoing embodiments, the content of the metallic material (Cr) is zero on the interfaces of the transparent conductive film material layers 205 and 308 and gradually increases toward the metallic material layers 203 and 310. Only the metallic material (Cr) remains on the interfaces of the metallic material layers 203 and 310. The mixed layers 204 and 309 are expected to have substantially the same effect even in the case where the content of the metallic material (Cr) gradually increases toward the metallic material layers 203 and 310, the content of the metallic material (Cr) is substantially zero on the interfaces of the transparent conductive film material layers 205 and 308, and only the metallic material (Cr) remains on the interfaces of the metallic material layers 203 and 310.

The present invention contributes to an improvement of reliability of solar cells and various facilities using the same.

1. A solar cell comprising a first electrode layer, a photoelectric conversion layer, and a second electrode layer that are sequentially stacked,
wherein the first electrode layer is a multilayer film including a transparent conductive film material layer, a mixed layer, and a metallic material layer that are stacked in this order when viewed from the photoelectric conversion layer, the mixed layer contains a metal of the metallic material layer and a transparent conductive material of the transparent conductive film material layer, and a content of the metallic material in the mixed layer gradually increases toward the metallic material layer.

2. A solar cell comprising a first electrode layer as a lower electrode layer, a photoelectric conversion layer, and a second electrode layer that are sequentially stacked on a surface of a substrate having electrical insulation,
wherein the first electrode layer is a multilayer film including a transparent conductive film material layer, a mixed layer, and a metallic material layer that are stacked in this order when viewed from the photoelectric conversion layer, the mixed layer contains a metal of the metallic material layer and a transparent conductive material of the transparent conductive film material layer, and a content of the metallic material in the mixed layer gradually increases toward the metallic material layer.

3. A solar cell comprising a second electrode layer as a lower electrode layer, a photoelectric conversion layer, and a first electrode layer that are sequentially stacked on a surface of a substrate having electrical insulation,
wherein the first electrode layer is a multilayer film including a transparent conductive film material layer, a mixed layer, and a metallic material layer that are stacked in this order when viewed from the photoelectric conversion layer, the mixed layer contains a metal of the metallic material layer and a transparent conductive material of the transparent conductive film material layer, and a content of the metallic material in the mixed layer gradually increases toward the metallic material layer.

4. The solar cell according to claim 1, wherein the content of the metallic material in the mixed layer is zero on an interface of the transparent conductive film material layer, the content of the metallic material gradually increases toward the metallic material layer, and only the metallic material remains on an interface of the metallic material layer.

5. A method of manufacturing a solar cell comprising a first electrode layer as a lower electrode layer, a photoelectric conversion layer, and a second electrode layer that are sequentially stacked, the method comprising the steps of:
forming the first electrode layer by sequentially stacking a metallic material layer and a transparent conductive film material layer on a surface of a substrate toward the photoelectric conversion layer;
stacking the photoelectric conversion layer having an amorphous phase on the transparent conductive film material layer; and
supplying a quantity of heat to the transparent conductive film material layer through the photoelectric conversion layer to crystallize the photoelectric conversion layer while forming a mixed layer on an interface between the transparent conductive film material layer and the metallic material layer by thermal diffusion, the mixed layer containing a metallic material of the metallic material layer and a transparent conductive material of the transparent conductive film material layer while a content of the metallic material gradually increases toward the metallic material layer.

6. A method of manufacturing a solar cell comprising a first electrode layer as a lower electrode layer, a photoelectric conversion layer, and a second electrode layer that are sequentially stacked,
the method comprising the steps of:
sequentially stacking a metallic material layer and a transparent conductive film material layer on a surface of a substrate toward the photoelectric conversion layer;
forming a mixed layer on an interface between the transparent conductive film material layer and the metallic material layer by thermal diffusion, the mixed layer containing a metallic material of the metallic material layer and a transparent conductive material of the transparent conductive film material layer while a content of the metallic material gradually increases toward the metallic material layer;
stacking the photoelectric conversion layer on the transparent conductive film material layer; and
forming the second electrode layer on the photoelectric conversion layer.

7. A method of manufacturing a solar cell comprising a first electrode layer, a photoelectric conversion layer, and a second electrode layer that are sequentially stacked, the method comprising the steps of:
forming the second electrode layer on a surface of a substrate;
stacking the photoelectric conversion layer on the second electrode layer;
stacking a transparent conductive film material layer on the photoelectric conversion layer;
stacking a metallic material layer on the transparent conductive film material layer; and
supplying a quantity of heat to the metallic material layer to form a mixed layer on an interface between the transparent conductive film material layer and the metallic material layer by thermal diffusion, the mixed layer containing a metallic material of the metallic material layer and a transparent conductive material of the transparent conductive film material layer while a content of the metallic material gradually increases toward the metallic material layer, the first electrode layer including the transparent conductive film material layer, the mixed layer, and the metallic material layer.

8. The method of manufacturing a solar cell according to claim 5, wherein the thermal diffusion heat-treats the interface between the metallic material layer and the transparent conductive film material layer to at least 300° C.

9. The method of manufacturing a solar cell according to claim 7, wherein at least one of atmospheric pressure plasma, flash lamp annealing, and laser ablation is performed in the thermal diffusion.
